(19) United States
(12) Patent Application Publication
(10) Pub. No.: US 2026/0251838 A1
(43) Pub. Date: Aug. 27, 2026

(54) DISPLAY APPARATUS

(71) Applicant: LG Display Co., Ltd., Seoul (KR)

(72) Inventor: Hyukkyu KWON, Paju-si (KR)

(21) Appl. No.: 19/428,290

(22) Filed: Dec. 21, 2025

(30) Foreign Application Priority Data
Feb. 26, 2025 (KR) 10-2025-0024780

(51) Int. Cl. F21V 8/00

(52) U.S. Cl. CPC G02B 6/0053

(57) ABSTRACT

A display apparatus includes a first light source package including a plurality of first light sources and a first substrate; a diffusion sheet disposed on the first light source package; a prism sheet disposed on the diffusion sheet; a light control film disposed on the prism sheet; a light guide plate disposed on the light control film and having a long side extending in a first direction and a short side extending in a second direction intersecting the first direction; and a second light source package including a plurality of second light sources disposed to face the long side of the light guide plate and a second substrate, in which the plurality of second light sources are protruded from the second substrate in the second direction and repeatedly disposed in the first direction and are each independently driven.

### CROSS REFERENCE TO RELATED APPLICATION

This application claims priority from and the benefit of Korean Patent Application No. 10-2025-0024780, filed on February 26, 2025, which is hereby incorporated by reference for all purposes as if fully set forth herein.

### BACKGROUND

### FIELD

Embodiments of the invention relate generally to a display apparatus.

### DISCUSSION OF THE BACKGROUND

As the information society develops, various demands for display apparatuses for displaying images are increasing, and various types of display apparatuses, such as a liquid crystal display (LCD) apparatus and an organic light-emitting diode (OLED) display apparatus, are being utilized.

The conventional display apparatuses do not restrict a viewing angle. However, for privacy and information protection reasons, restrictions on a viewing angle have been increasingly required recently. For example, a display apparatus used as an in-vehicle information medium may provide high-quality images to a front-seat passenger, but it is necessary to restrict a viewing angle for a driver for the sake of driving safety.

The above information disclosed in this Background section is only for understanding of the background of the inventive concepts, and, therefore, it may contain information that does not constitute prior art.

### SUMMARY

The present disclosure provides a display apparatus capable of displaying different images based on a viewing angle.

The present disclosure also provides a display apparatus in which a limited viewing angle area may be changed.

The present disclosure also provides a display apparatus in which the convenience of a user may be improved due to the change in the limited viewing angle area.

Additional features of the inventive concepts will be set forth in the description which follows, and in part will be apparent from the description, or may be learned by practice of the inventive concepts.

According to an embodiment of the present disclosure, a display apparatus includes a first light source package including a plurality of first light sources and a first substrate, a diffusion sheet disposed on the first light sources, a prism sheet disposed on the diffusion sheet, a light control film disposed on the prism sheet, a light guide plate disposed on the light control film and having a long side extending in a first direction and a short side extending in a second direction intersecting the first direction, and a second light source package including a plurality of second light sources disposed to face the long side of the light guide plate and a second substrate, wherein the plurality of second light sources are protruded from the second substrate in the second direction and repeatedly disposed in the first direction and are each independently driven.

The display apparatus may include a first display area configured to be operated in a share mode with a wide viewing angle; and a second display area configured to be variably switched from the share mode with the wide viewing angle to a private mode with a narrow viewing angle is switched.

The first display area and the second display area may be disposed in the first direction.

When the second display area operates in the share mode, some of the plurality of second light sources corresponding to the second display area may be turned on, and when the second display area operates in the private mode, some of the plurality of second light sources corresponding to the second display area may be turned off.

A boundary between the first display area and the second display area may extend in the second direction, and the boundary between the first display area and the second display area may be variably changed in the first direction based on turn-on and turn-off of the plurality of second light sources.

The light guide plate may include a plurality of light guide patterns disposed on a bottom surface of the light guide plate, and a density per unit area of the plurality of light guide patterns increases as the light guide patterns are farther away from the plurality of second light sources.

The plurality of second light sources may be disposed on both one side and the other side of the light guide plate in the second direction, and a density per unit area of the plurality of light guide patterns may increase from the long side of the light guide plate toward a central portion of the light guide plate in the second direction.

Each of the plurality of light guide patterns may have a pyramidal shape protruding toward the light control film, and slopes of the four side surfaces forming the pyramidal shape may be all the same.

The light control film may include a plurality of light-shielding patterns and patterned insulating films between the light-shielding patterns, and the plurality of light-shielding patterns may extend in the second direction and are repeatedly disposed in the first direction.

The plurality of light-shielding patterns may have a same thickness in a thickness direction and are repeatedly disposed at regular intervals in the first direction.

The prism sheet may include a first prism sheet and a second prism sheet that are sequentially stacked in a thickness direction, and a prism pattern of the first prism sheet and a prism pattern of the second prism sheet may have axes that are orthogonal to each other.

The display apparatus may include a display panel disposed on the light guide plate, in which the display panel includes a lower substrate, an upper substrate, and a liquid crystal layer disposed between the lower substrate and the upper substrate.

The plurality of first light sources may be disposed below the diffusion sheet.

The plurality of second light sources may be disposed on either one side or the other side of the light guide plate in the second direction.

According to another embodiment of the present disclosure, a display apparatus may include a first display area that operates in a share mode with a wide viewing angle, a second display area which is disposed at one side of the first display area in a first direction and in which the share mode with the wide viewing angle and a private mode with a narrow viewing angle are variably switched, a boundary disposed between the first display area and the second display area, which extends in a second direction intersecting the first direction, a plurality of first light sources disposed across the first display area and the second display area, a light guide plate disposed on the first light sources, and a plurality of second light sources that are disposed to face a side surface of the light guide plate and are repeatedly disposed in the first direction, in which the boundary disposed between the first display area and the second display area changeably moves in the first direction based on turned-on and turned-off states of the plurality of second light sources.

When the first display area operates in the share mode, a remaining ones of the plurality of second light sources corresponding to the first display area may be turned on.

The plurality of second light sources may be disposed on both one side and the other side of the light guide plate in the second direction, and a density per unit area of the plurality of light guide patterns may increase from the side surface of the light guide plate toward a central portion of the light guide plate in the second direction.

It is to be understood that both the foregoing general description and the following detailed description are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this specification, illustrate embodiments of the invention, and together with the description serve to explain the inventive concepts.

FIG. 1 is a schematic plan view of a display apparatus according to an embodiment.

FIG. 2 is an exploded schematic perspective view of the display apparatus according to an embodiment.

FIG. 3 is a schematic cross-sectional view along line A-A’ in FIG. 1.

FIG. 4 is a schematic view showing a second light guide plate and its peripheral cross-sectional structure according to an embodiment.

FIG. 5 is a schematic view showing a light guide pattern of a second light guide plate according to an embodiment.

FIG. 6 is a schematic graph showing the density of the light guide pattern in a second direction according to an embodiment.

FIG. 7 is a schematic view of the display apparatus in which both a first display area and a second display area operate in a share mode.

FIG. 8 is a schematic view of the display apparatus in which the first display area operates in the share mode and the second display area operates in a private mode.

FIG. 9 is an exploded schematic perspective view of a display apparatus according to another embodiment.

FIG. 10 is a schematic view showing a second light guide plate and its peripheral cross-sectional structure according to another embodiment.

FIG. 11 is a schematic plan view of the display apparatus according to another embodiment.

FIG. 12 is an exploded schematic perspective view of the display apparatus according to another embodiment.

### DETAILED DESCRIPTION

In the following description, for the purposes of explanation, numerous specific details are set forth in order to provide a thorough understanding of embodiments or implementations of the invention. As used herein “embodiments” and “implementations” are

interchangeable words that are non-limiting examples of devices or methods employing one or more of the inventive concepts disclosed herein. It is apparent, however, that embodiments may be practiced without these specific details or with one or more equivalent arrangements. In other instances, well-known structures and devices are shown in block diagram form in order to avoid unnecessarily obscuring embodiments. Further, embodiments may be different, but do not have to be exclusive. For example, specific shapes, configurations, and characteristics of an embodiment may be used or implemented in another embodiment without departing from the inventive concepts.

Unless otherwise specified, the illustrated embodiments are to be understood as providing features of varying detail of some ways in which the inventive concepts may be implemented in practice. Therefore, unless otherwise specified, the features, components, modules, layers, films, panels, regions, and/or aspects, etc. (hereinafter individually or collectively referred to as “elements”), of the embodiments may be otherwise combined, separated, interchanged, and/or rearranged without departing from the inventive concepts.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order. Also, like reference numerals denote like elements.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Further, the D1-axis, the D2-axis, and the D3-axis are not limited to three axes of a rectangular coordinate system, such as the x, y, and z – axes, and may be interpreted in a broader sense. For example, the D1-axis, the D2-axis, and the D3-axis may be perpendicular to one another, or may represent different directions that are not perpendicular to one another. For the purposes of this disclosure, “at least one of X, Y, and Z” and “at least one selected from the group consisting of X, Y, and Z” may be construed as X only, Y only, Z only, or any combination of two or more of X, Y, and Z, such as, for instance, XYZ, XYY, YZ, and ZZ. As used herein, the term “and/or” includes any and all combinations of one or more of the associated listed items.

Although the terms “first,” “second,” etc. may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the exemplary term “below” can encompass both an orientation of above and below. Furthermore, the apparatus may be otherwise oriented (e.g., rotated 90 degrees or at other orientations), and, as such, the spatially relative descriptors used herein interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Embodiments are described herein with reference to sectional and/or exploded illustrations that are schematic illustrations of idealized embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

As customary in the field, some embodiments are described and illustrated in the accompanying drawings in terms of functional blocks, units, and/or modules. Those skilled in the art will appreciate that these blocks, units, and/or modules are physically implemented by electronic (or optical) circuits, such as logic circuits, discrete components, microprocessors, hard-wired circuits, memory elements, wiring connections, and the like, which may be formed using semiconductor-based fabrication techniques or other manufacturing technologies. In the case of the blocks, units, and/or modules being implemented by microprocessors or other similar hardware, they may be programmed and controlled using software (e.g., microcode) to perform various functions discussed herein and may optionally be driven by firmware and/or software. It is also contemplated that each block, unit, and/or module may be implemented by dedicated hardware, or as a combination of dedicated hardware to perform some functions and a processor (e.g., one or more programmed microprocessors and associated circuitry) to perform other functions. Also, each block, unit, and/or module of some embodiments may be physically separated into two or more interacting and discrete blocks, units, and/or modules without departing from the scope of the inventive concepts. Further, the blocks, units, and/or modules of some embodiments may be physically combined into more complex blocks, units, and/or modules without departing from the scope of the inventive concepts.

Unless otherwise defined, all terms (including technical and scientific terms) used herein have the same meaning as commonly understood by one of ordinary skill in the art to which this disclosure is a part. Terms, such as those defined in commonly used dictionaries, should be interpreted as having a meaning that is consistent with their meaning in the context of the relevant art and should not be interpreted in an idealized or overly formal sense, unless expressly so defined herein.

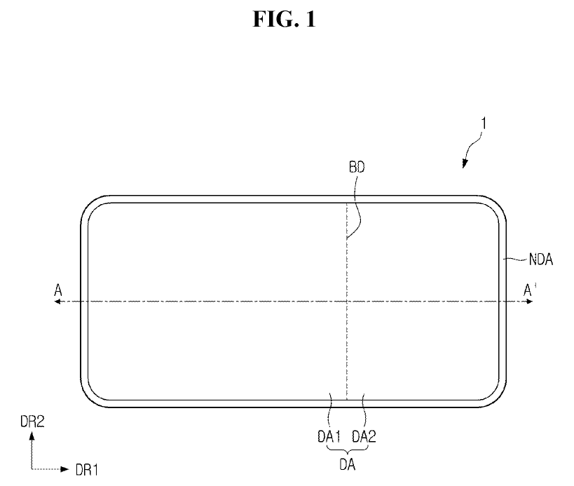

FIG. 1 is a schematic plan view of a display apparatus according to an embodiment.

Referring to FIG. 1, a display apparatus 1 may include both a display function of displaying an image and a touch sensing function of sensing a user’s touch, but is not limited thereto. For example, the display apparatus 1 may include only one of the display function of displaying an image and the touch sensing function of sensing a user’s touch.

The display apparatus 1 may be an electroluminescent display apparatus or a micro light-emitting diode display apparatus that includes a touch sensor. Alternatively, the electroluminescent display apparatus including a touch sensor may be an organic light-emitting diode (OLED) display apparatus, a quantum-dot light-emitting diode display apparatus, or an inorganic light-emitting diode display apparatus.

The display apparatus 1 according to the present embodiment may be a vehicle display apparatus, but is not limited thereto. For example, the description of the display apparatus 1 may be applied without limitation to the type of the apparatus as long as a display apparatus is an apparatus including a display function.

The display apparatus 1 may have a length extending in a first direction DR1and have a width extending in a second direction DR2. The first direction DR1 and the second direction DR2 may intersect each other or may be perpendicular, but are not limited thereto. The display apparatus 1 may have a long side extending in the first direction DR1 and a short side extending in the second direction DR2. However, in another embodiment, the display apparatus 1 may be a square shape having the same sides extending in the first direction DR1 and extending in the second direction DR2.

When the display apparatus 1 according to the present embodiment is a vehicle display apparatus, the display apparatus 1 may include a function of manipulating at least some of various functions of a vehicle, a function of displaying various information about the vehicle, etc.

When the display apparatus 1 according to the present embodiment is a vehicle display apparatus, the display apparatus 1 may be disposed on a dashboard of a vehicle. The display apparatus 1 may be disposed across a driver’s seat and a front passenger’s seat that are disposed at front seats of a vehicle, but is not limited thereto.

A direction in which the display apparatus 1 is disposed to cross the driver’s seat and the front passenger’s seat may correspond to the first direction DR1. In particular, the display apparatus 1 may extend in the first direction DR1 and may be disposed across the driver’s seat and the front passenger’s seat in the first direction DR1.

When the display apparatus 1 is a vehicle display apparatus, both a driver DRIVER sitting in the driver’s seat and a passenger CO-DRIVER sitting in the front passenger’s seat may use the display apparatus 1. The display apparatus 1 may provide the same image to both the driver DRIVER sitting in the driver’s seat and the front passenger CO-DRIVER sitting in the front passenger’s seat or provide different images to each.

The display apparatus 1 may include a display area DA and a non-display area NDA.

The display area DA may be an area in which a screen may be displayed. Light may be emitted externally from the display area DA. The display area DA may further include a function of sensing a user’s touch. In this case, the display area DA may correspond to a touch sensing area, but is not limited thereto.

A planar shape of the display area DA may correspond to the planar shape of the display apparatus 1, but is not limited thereto. The display area DA may have a long side extending in the first direction DR1 and a short side extending in the second direction DR2.

The display area DA may include a first display area DA1 and a second display area DA2. The first display area DA1 and the second display area DA2 may be disposed continuously in the first direction DR1. In particular, the second display area DA2 may be disposed at one side of the first display area DA1 in the first direction DR1, and the first display area DA1 may be disposed at the other side of the second display area DA2 in the first direction DR1.

The first display area DA1 may operate in a first mode, and the second display area DA2 may operate in both the first mode and a second mode.

For example, the first mode may be a share mode, which does not limit a side viewing angle of the display apparatus 1. The second mode may be a private mode, which limits the side viewing angle of the display apparatus 1. In particular, the share mode may have a wide viewing angle, and the private mode may have a narrow viewing angle.

Here, the side viewing angle may be a side viewing angle in the first direction DR1.

The first display area DA1 may maintain the share mode during the operation of the display apparatus 1. The second display area DA2 may selectively operate in the share mode and the private mode during the operation of the display apparatus 1. During the operation of the display apparatus 1, the second display area DA2 may change from the share mode to the private mode or from the private mode to the share mode.

When the display apparatus 1 is applied to a vehicle display apparatus, the first display area DA1 may be disposed at a location adjacent to the driver’s seat, and the second display area DA2 may be disposed at a location adjacent to the front passenger’s seat.

When each of the first display area DA1 and the second display area DA2 operates in the share mode, images, videos, and the like displayed in the first display area DA1 and images, videos, and the like displayed in the second display area DA2 may be provided to both the driver sitting in the driver’s seat and the front passenger sitting in the front passenger’s seat.

When the second display area DA2 operates in the private mode, the images, videos, and the like displayed in the second display area DA2 may be provided to the front passenger sitting in the front passenger’s seat and may not be provided to the driver sitting in the driver’s seat.

The second display area DA2 of the display apparatus 1 according to the present embodiment may have a variable size. For example, a boundary BD between the first display area DA1 and the second display area DA2 may be moved to one side and the other in the first direction DR1. Accordingly, enhanced convenience may be provided to the user of the display apparatus 1. Furthermore, the efficiency of the display apparatus 1 may be improved and the manufacturing process of the display apparatus 1 may be simplified, thereby reducing power consumption and production energy.

The non-display area NDA may be an area in which no screen is displayed. Light may not be emitted externally from the non-display area NDA, but is not limited thereto. The non-display area NDA may be located adjacent to the display area DA. The non-display area NDA may surround the display area DA, but the embodiments of the present disclosure are not limited thereto. A bezel area of the display apparatus 1 may be defined by the non-display area NDA, but the embodiments of the present disclosure are not limited thereto.

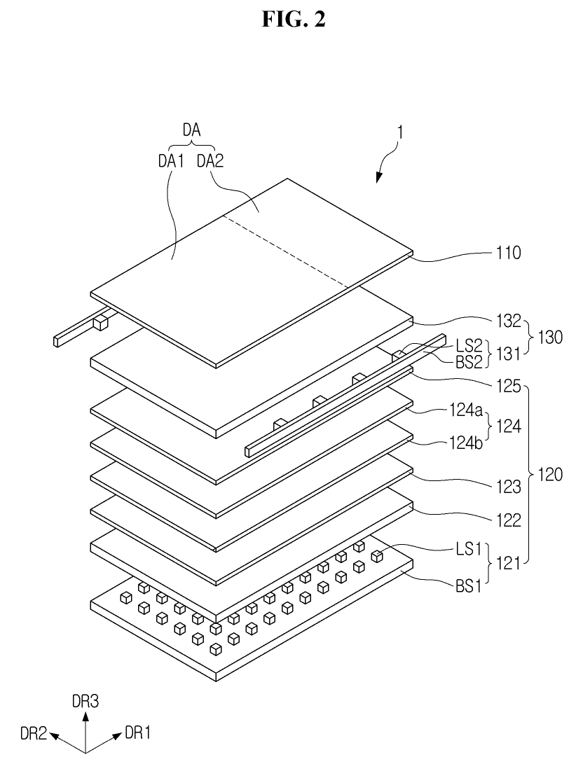

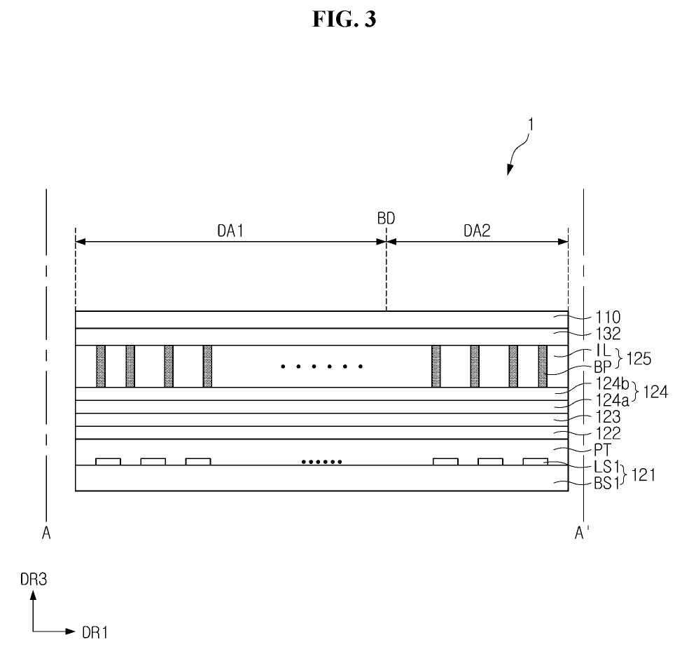

FIG. 2 is an exploded schematic perspective view of the display apparatus according to an embodiment. FIG. 3 is a schematic cross-sectional view along line A-A’ in FIG. 1.

Referring to FIGS. 1, 2, and 3, the display apparatus 1 according to an embodiment may include a display panel 110 that includes pixels and displays images, and first and second backlight units 120 and 130 that are disposed on a back surface of the display panel 110 and emit light to a front surface of the display panel 110. Although not shown, the display apparatus 1 may further include a panel guide, a top case, a bottom cover, and the like that fixedly store the display panel 110 and the first and second backlight units 120 and 130.

The display panel 110 may be a liquid crystal panel and may include a lower substrate and an upper substrate bonded to face each other, and a liquid crystal layer interposed between the substrates.

The lower substrate may include gate lines and data lines arranged to intersect each other, and liquid crystal cells formed at intersections of the gate lines and the data lines. The liquid crystal cells may include thin film transistors disposed at the intersections of the gate lines and the data lines, and a pixel electrode that receives a data voltage applied to the data line through the thin film transistor when the thin film transistor is turned on.

On the upper substrate, color filters for implementing multiple colors by including red, green, and blue, a black matrix for dividing the color filters and blocking light passing through the liquid crystal layer, and a common electrode for applying voltage to the liquid crystal layer are disposed.

The liquid crystal cells are driven by an electric field generated by a potential difference between data voltages supplied to the pixel electrodes through the data lines and a common voltage supplied to the common electrode, thereby controlling the amount of light passing through the display panel 110.

The first and second backlight units 120 and 130 may be disposed below the display panel 110 and provide light to the display panel 110. The first backlight unit 120 may be disposed below the display panel 110, and the second backlight unit 130 may be interposed between the first backlight unit 120 and the display panel 110.

The first backlight unit 120 may include a first light source package 121, a first light guide plate 122, a diffusion sheet 123, a prism sheet 124, and a light control film 125.

Planar shapes of the first light guide plate 122, the diffusion sheet 123, the prism sheet 124, and the light control film 125 may correspond to the planar shape of the display apparatus 1. In particular, the first light guide plate 122, the diffusion sheet 123, the prism sheet 124, and the light control film 125 may have long sides extending in the first direction DR1 and short sides extending in the second direction DR2.

The first light source package 121 may include a first light source LS1 and a first light source substrate BS1. The first light source LS1 may be provided as a plurality of first light sources, and the plurality of first light sources LS1 may be mounted on the first light source substrate BS1. The plurality of first light sources LS1 may be repeatedly disposed in the first direction DR1 and the second direction DR2 on the first light source substrate BS1.

The plurality of first light sources LS1 may be driven by receiving power through the first light source substrate BS1 and be configured to generate light. Although not limited thereto, the first light source LS1 may generate light using various light sources, such as a cold cathode fluorescent lamp (CCFL), an external electrode fluorescent lamp (EEFL), a hot cathode fluorescent lamp (HCFL), a light emitting diode (LED), etc.

The first light source substrate BS1 may provide a space in which the first light source LS1 may be disposed. The first light source substrate BS1 may have a circuit board mounted thereon for the operation of the first light source LS1. The first light source substrate BS1 may control the first light source LS1 according to electrical signals supplied through wirings of the circuit board, thereby allowing the first light source LS1 to emit light.

The first light source package 121 may be disposed below the first light guide plate 122. Accordingly, light emitted from the first light source package 121 may be incident on a lower surface of the first light guide plate 122. However, the arrangement of the first light source package 121 is not limited thereto. For example, the first light source package 121 may be disposed on one side surface of the first light guide plate 122. In particular, the first light source package 121 and the first light source LS1 may be disposed to face the one side surface of the first light guide plate 122. Accordingly, the light emitted from the first light source package 121 may be incident on a bottom surface of the first light guide plate 122 and emitted to an upper surface of the first light guide plate 122.

The display apparatus 1 may further include a light source protection layer PT. The light source protection layer PT may be disposed on the first light source package 121 and disposed to cover the first light source LS1. The light source protection layer PT can protect the first light sources LS1. The light source protection layer PT may be formed of a resin, but is not limited thereto.

The first light guide plate 122 may be disposed on the first light source package 121. The first light guide plate 122 is disposed to face the first light source package 121 and guides the light incident from the first light source package 121 to be emitted upward in a third direction DR3 (or thickness direction).

In an embodiment, the first light guide plate 122 may be formed of a light-transmissive material, for example, a plastic material such as polymethyl methacrylate (PMMA) or a material selected from polycarbonate (PC)-based materials. However, the material of the first light guide plate 122 is not limited to the above materials, and the first light guide plate 122 may be formed of other materials.

The diffusion sheet 123 may be disposed on the first light guide plate 122. The diffusion sheet 123 may diffuse the light emitted from the first light guide plate 122, thereby improving brightness uniformity based on a viewing angle. The diffusion sheet 123 may be formed of a PET or PC resin and may include a particle coating layer that serves as a diffuser.

The prism sheet 124 may be disposed on the diffusion sheet 123. The prism sheet 124 may condense the light emitted from the first light guide plate 122 or the diffusion sheet 123 so that a traveling direction of light is close to a normal direction of the display panel 110, thereby improving the front brightness of the display panel 110.

The prism sheet 124 may include a first prism sheet 124a and a second prism sheet 124b. Each of the first prism sheet 124a and the second prism sheet 124b may include a prism pattern. A prism pattern of the first prism sheet 124a and a prism pattern of the second prism sheet 124b may have axes that are orthogonal to each other.

Since the second light source package 131 is disposed on one side and the other side of a second light guide plate 132 in the second direction DR2 and the prism sheet 124 includes the first prism sheet 124a and the second prism sheet 124b, the brightness of the display apparatus 1 may be improved.

A light control film (LCF) 125 may be disposed on the prism sheet 124. In particular, the light control film (LCF) 125 may be disposed on the first prism sheet 124a. The light control film 125 may control a light emission profile of the first backlight unit 120. For example, the light control film 125 may adjust view angles of the light emitted from the first backlight unit 120 in a left-right direction (first direction DR1) and/or vertical direction (second direction DR2) to narrow viewing angles.

The light control film 125 may include a plurality of light-shielding patterns BP and patterned insulating films IL that fill space (or gap) between the light-shielding patterns BP. Although not shown, the light control film 125 may further include a lower substrate and an upper substrate with the light-shielding patterns BP and the patterned insulating films IL interposed therebetween.

The light-shielding patterns BP may include a black dye, such as carbon black. The light-shielding patterns BP may have a predetermined thickness in the third direction DR3 (or thickness direction) and extend parallel to the second direction DR2. The light-shielding pattern BP may be provided as a plurality of light-shielding patterns and repeatedly disposed in the first direction DR1.

A distance between adjacent light-shielding patterns BP in the first direction DR1 may be constant throughout the display area DA, but is not limited thereto. The plurality of light-shielding patterns BP may all have the same thickness, but are not limited thereto.

For example, the distance between adjacent light-shielding patterns BP and the thickness of the plurality of light-shielding patterns BP may be the same across the first display area DA1 and the second display area DA2, but are not limited thereto.

Accordingly, when the distance between adjacent light-shielding patterns BP is constant across the entire area and the plurality of light-shielding patterns BP all have the same thickness, the light control film 125 may more smoothly restrict an emission angle of the light emitted from the first light source package 121 so that the traveling direction may be set to form a narrow angle. Furthermore, in this case, a more uniform amount of light may be provided across the entire display area DA, thereby improving clarity across the entire display area DA.

A traveling path of the light passing through the light control film 125 may be limited by the light-shielding pattern BP. The light control film 125 may adjust the transmittance of the light emitted from the first light source package 121 and emit the light, thereby enhance the contrast and clarity of images, videos, and the like displayed in the display area DA.

Furthermore, the light control film 125 may restrict the emission angle of the light emitted from the first light source package 121 using the light-shielding pattern BP.

The traveling path of the light passing through the light control film 125 may be limited by the light-shielding pattern BP. The light control film 125 may suppress or prevent the light emitted from the first light source package 121 from traveling to one side or the other side in the first direction DR1 using the light-shielding pattern BP.

Among the light emitted from the first light source package 121, light traveling in the third direction DR3 and traveling to one side or the other side in the first direction DR1 may be blocked by the light control film 125. Accordingly, the traveling direction of the light, which is emitted from the first light source package 121 and passes through the light control film 125, may have a narrow angle.

Accordingly, most of the light emitted from the first light source package 121 in the first display area DA1 may travel toward the driver, and most of the light may not be perceived by the front passenger. Most of the light emitted from the first light source package 121 in the second display area DA2 may travel toward the front passenger, and most of the light may not be perceived by the driver.

The second backlight unit 130 may be disposed on the first backlight unit 120. The second backlight unit 130 may include a second light source package 131 and a second light guide plate 132.

The second light guide plate 132 may be disposed on the light control film 125. The second light guide plate 132 may guide light emitted from the second light source package 131 and emit the light upward in the third direction DR3. The light emitted from the second light source package 131 may be incident on side surfaces of the second light guide plate 132.

The planar shape of the second light guide plate 132 may correspond to the planar shape of the display apparatus 1. In particular, the second light guide plate 132 may have a long side extending in the first direction DR1 and a short side extending in the second direction DR2.

The second light guide plate 132 may be formed of substantially the same material as the first light guide plate 122, but is not limited thereto.

The second light source package 131 may be disposed on the side surfaces of the second light guide plate 132. The second light source package 131 may be disposed to face (or be opposite to) the long side of the second light guide plate 132. The second light source package 131 may extend in the first direction DR1.

The second light source package 131 may be disposed on both one side and the other side of the second light guide plate 132 in the second direction DR2, but is not limited thereto. In particular, the second light guide plate 132 may be interposed between the second light source packages 131 in the second direction DR2. More particularly, the second light source package 131 may be disposed to face each other with the second light guide plate 132 interposed therebetween.

The second light source package 131 may include a second light source LS2 and a second light source substrate BS2. The second light source substrate BS2 may extend in the first direction DR1. The second light source LS2 may be provided as a plurality of second light sources, and the plurality of second light sources LS2 may be mounted on the second light source substrate BS2. In particular, the second light source LS2 may be protruded from the light source substrate BS2 in the second direction DR2. The plurality of second light sources LS2 may be disposed on the second light source substrate BS2 and may be repeatedly disposed in the first direction DR1.

In FIG. 2, for convenience of description, only four second light sources LS2 disposed on the second light source substrate BS2 are shown, but the embodiments of the present disclosure are not limited thereto, and four or more second light sources LS2 may be provided.

As the plurality of second light sources LS2 are repeatedly disposed in the first direction DR1, the viewing angle in the first direction DR1 in the share mode may be improved.

The plurality of second light sources LS2 may be driven by receiving power through the second light source substrate BS2 and may generate light. Although not limited thereto, the second light source LS2 may generate light using various light sources, such as a CCFL, an EEFL, an HCFL, an LED, etc.

The plurality of second light sources LS2 may each be driven independently.

Accordingly, the first display area DA1 and the second display area DA2 may be changed. However, in another embodiment, the plurality of second light sources LS2 may be driven simultaneously.

The second light source substrate BS2 may provide a space in which the second light source LS2 may be disposed. The second light source substrate BS2 may have a circuit board mounted thereon for the operation of the second light source LS2. The second light source substrate BS2 may control the second light source LS2 according to electrical signals supplied through wirings of the circuit board, thereby allowing the second light source LS2 to emit light.

The second light guide plate 132 may refract incident light emitted from the second light source package 131 not only in the second direction DR2 but also in the first direction DR1, thereby implementing the share mode of the display apparatus 1.

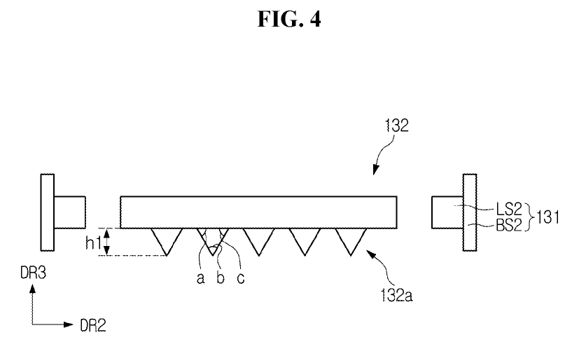

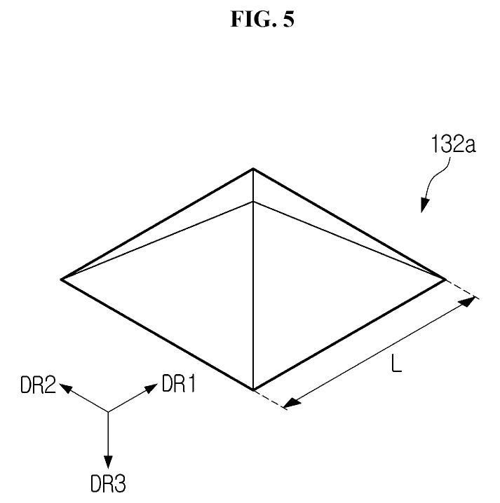

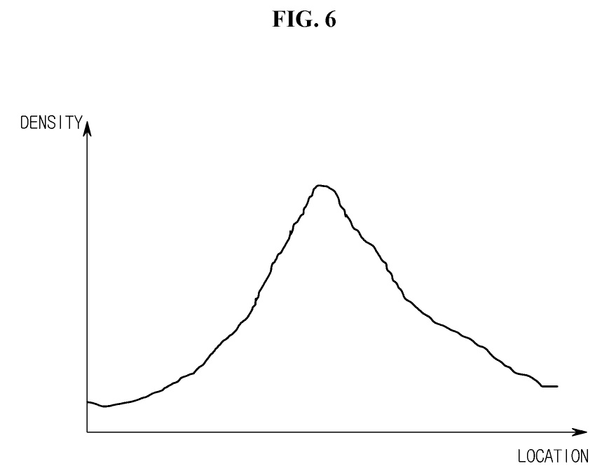

FIG. 4 is a schematic view showing a second light guide plate and its peripheral cross-sectional structure according to an embodiment. FIG. 5 is a schematic view showing a light guide pattern of a second light guide plate according to an embodiment. FIG. 6 is a schematic graph showing the density of the light guide pattern in a second direction according to an embodiment.

In FIG. 6, a horizontal axis (i.e., X-axis) may represent the location of the second light guide plate 132 in the second direction DR2, and a vertical axis (i.e., Y-axis) may represent a density per unit area of the light guide pattern 132a. In particular, the vertical axis (i.e., Y-axis) may represent a location from one side of the second light guide plate 132 in the second direction DR2 to the other side in the second direction DR2. The higher the density per unit area of the light guide pattern 132a, more light guide patterns 132a may be disposed per unit area.

Referring further to FIGS. 4, 5, and 6, polygonal protruding light guide patterns 132a may be formed on the back surface of the second light guide plate 132. The light guide patterns 132a may be embossed on the back surface of the second light guide plate 132 through injection molding or printing. In another embodiment, the light guide patterns 132a may be formed to be recessed in the back surface of the second light guide plate 132.

In an embodiment, the light guide patterns 132a may have a pyramidal shape. In this case, the light guide patterns 132a may have a symmetrical shape in which slopes of all four side surfaces forming a pyramid are the same or substantially similar. Accordingly, since the light emitted from the second light source packages 131 disposed on the one side and the other side of the second light guide plate 132 in the second direction DR2 is uniformly refracted or dispersed to the one side and the other side in the first direction DR1, a portion of the display area DA corresponding to an area in which the second light source LS2 is turned on may operate more smoothly in the share mode.

In an embodiment, a length L of one side of the symmetrical pyramid may range from about 10 µm to about 50 µm. For example, the length L of one side of the symmetrical pyramid may be about 30 µm. In addition, in an embodiment, an angle “a” between the back surface of the second light guide plate 132 and one side surface of the symmetrical pyramid may range from about 20° to about 60°. For example, the angle “a” may be about 40°. An angle “c” between the back surface of the second light guide plate 132 and the other side surface of the symmetrical pyramid may range from about 20° to about 60°. For example, the angle “c” may be about 40°. A vertex angle “b” of the symmetrical pyramid may be about 100°.

The angle “a” between the back surface of the second light guide plate 132 and the one side surface of the symmetrical pyramid and the angle “c” between the back surface of the second light guide plate 132 and the other side surface of the symmetrical pyramid may be the same, but are not limited thereto.

A height h1 of the symmetrical pyramid may be determined based on the size and slopes of four side surfaces and may, for example, range from about 5 μm to about 30 μm. However, the present embodiment is not limited thereto.

The light guide patterns 132a may be disposed to be regularly or irregularly spaced apart from each other in the second direction DR2. The density per unit area of the light guide pattern 132a may vary based on the location of the second light guide plate 132.

The density per unit area of the light guide pattern 132a may vary in the second direction DR2.

As shown in FIG. 6, the density per unit area of the light guide pattern 132a on the second light guide plate 132 may decrease as the light guide patterns 132a are near the second light source package 131 and increase as the light guide patterns 132a are farther away from the second light source package 131. As the second light source packages 131 are disposed on the one side and the other side of the second light guide plate 132 in the second direction DR2, the density per unit area of the light guide pattern 132a on the second light guide plate 132 may increase near a central portion of the second light guide plate 132 (or, a central portion of the plurality of light guide patterns 132a) in the second direction DR2 and decrease from the central portion of the light guide plate 132 toward the one side and the other side in the second direction DR2.

As the density per unit area of the light guide pattern 132a increases as the light guide patterns 132a are farther away from the second light source package 131, even when the amount of light reaching a distant area from the second light source package 131 is insufficient, a percentage of light refracted or dispersed by more light guide patterns 132a in the first direction DR1 may increase.

Accordingly, light passing through the second light guide plate 132 may be more uniform across the entire display area DA. Furthermore, the uniformity of luminance based on the viewing angle of the display apparatus 1 may be improved.

The density per unit area of the light guide pattern 132a on the second light guide plate 132 may be the same in the first direction DR1, but is not limited thereto.

The light incident from the second light source package 131 to the second light guide plate 132 may have emission angle controlled by the light guide patterns 132a formed on the back surface of the second light guide plate 132. Since the light guide pattern 132a is formed in a symmetrical pyramid shape or dot shape, the light emitted from the second light source packages 131 disposed on the one side and the other side of the second light guide plate 132 in the second direction DR2 may be refracted at the four surfaces or curved surfaces of the light guide patterns 132a. Accordingly, the light emitted from the second light source package 131 may be refracted and emitted from the light guide patterns 132a not only in the second direction DR2 but also in the first direction DR1.

The light emitted from the second light source package 131 may be refracted and emitted to one side and the other side in the first direction DR1 while passing through the second light guide plate 132, and the light emitted from the second light source package 131 may be emitted at a wide angle in the first direction DR1.

In particular, at least a portion of the display area DA corresponding to the area in which the second light source LS2 emitting light (turned on) from the second light source package 131 is disposed may display images and videos in the share mode.

In the present disclosure, the term “at least a portion of the display area DA corresponding to the area in which the turned-on second light source LS2 is disposed” may refer to at least a portion of the display area DA located on one or the other side of the turned-on second light source LS2 in the second direction DR2.

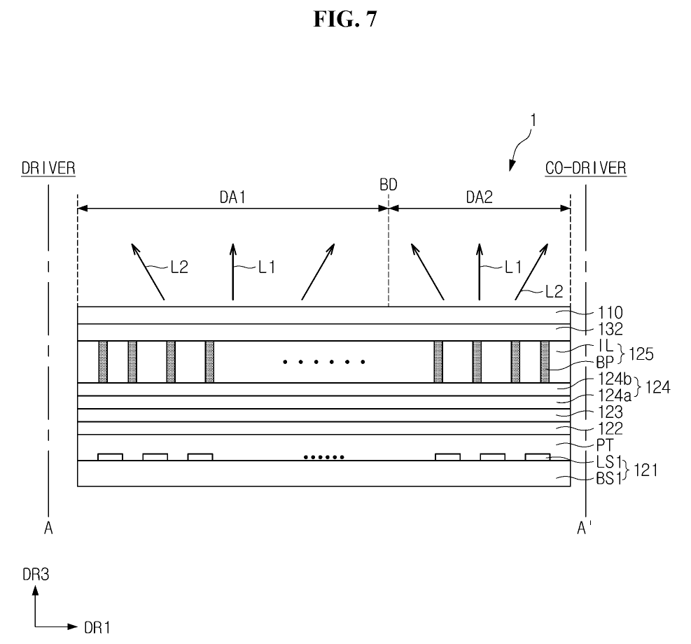

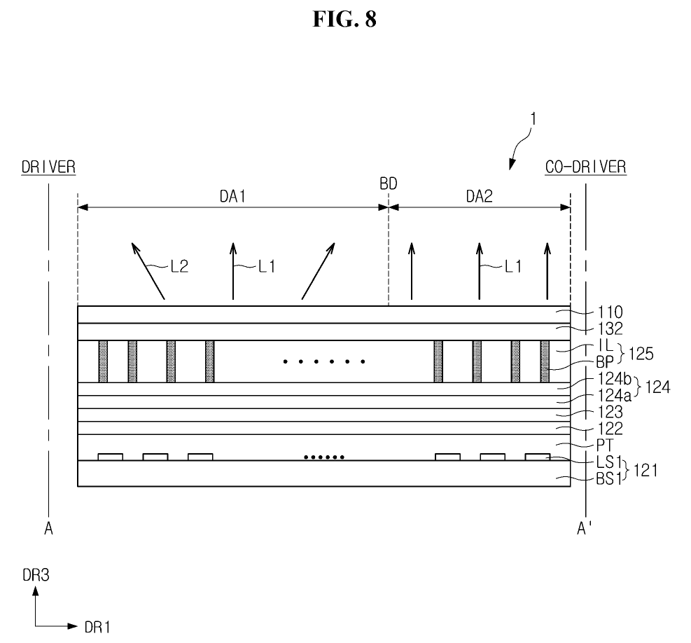

FIG. 7 is a schematic view of the display apparatus in which both a first display area and a second display area operate in a share mode. FIG. 8 is a schematic view of the display apparatus in which the first display area operates in the share mode and the second display area operates in a private mode.

Referring further to FIGS. 7 and 8, each of the plurality of second light sources LS2 may be independently turned on and off. Accordingly, when at least some of the plurality of second light sources LS2 are turned on, at least a portion of the display area DA corresponding to the area in which the turned-on second light source LS2 is disposed may be variably switched to the share mode.

The light that is emitted from the first light source package 121 and passes through the light control film 125 may have a narrow viewing angle. Accordingly, when there is no light emitted from the second light source package 131, both the first display area DA1 and the second display area DA2 may operate in the private mode.

As shown in FIG. 7, when the second light sources LS2 disposed in the areas corresponding to the first display area DA1 and the second display area DA2 are turned on and emits light, the first display area DA1 and the second display area DA2 may emit both light L1 with a narrow viewing angle, which is emitted from the first light source package 121 and passes through the light control film 125, and light L2 with a wide viewing angle in the first direction DR1, which is emitted from the second light source package 131 and passes through the second light guide plate 132.

Accordingly, both the first display area DA1 and the second display area DA2 may operate in the share mode.

As shown in FIG. 8, some of the second light sources LS2 disposed in the area corresponding to the first display area DA1 may be turned on to emit light, and the remaining ones of the second light sources LS2 disposed in the area corresponding to the second display area DA2 may be turned off not to emit light.

In this case, the first display area DA1 may emit both the light L1 with a narrow viewing angle, which is emitted from the first light source package 121 and passes through the light control film 125, and the light L2 with a wide viewing angle, which is emitted from the second light source package 131 and passes through the second light guide plate 132 in the first direction DR1. The second display area DA2 may emit only the light L1 with a narrow viewing angle, which is emitted through the light control film 125 and passes through the second light guide plate 132.

Accordingly, the first display area DA1 may operate in the share mode, and the second display area DA2 may operate in the private mode.

Consequently, each of the plurality of second light sources LS2 may be operated independently, and the first display area DA1 and the second display area DA2 may be variably switched between the share mode and the private mode by turning the second light sources LS2 on and off. Furthermore, by adjusting the number and arrangement of turned-on second light sources LS2, the boundary BD between the first display area DA1 and the second display area DA2 may be adjusted in the first direction DR1.

When the first display area DA1 operates only in the share mode, the first light sources LS1 and the second light sources LS2 disposed in the area corresponding to the first display area DA1 may be maintained in the turned-on state.

Here, the first light sources LS1 disposed in the area corresponding to the first display area DA1 may be the first light sources LS1 disposed in the first display area DA1 in the third direction DR3. The second light sources LS2 disposed in the area corresponding to the first display area DA1 may be the second light sources LS2 disposed on one side and the other side of the first display area DA1 in the second direction DR2.

When the second display area DA2 variably operates in the share mode and the private mode, the first light sources LS1 disposed in the area corresponding to the second display area DA2 may be maintained in the turned-on state, and the second light sources LS2 disposed in the area corresponding to the second display area DA2 may be variably switched between the turned-on state and the turned-off state. Accordingly, based on the arrangement of the second light sources LS2 whose turn-on and turn-off states are variably switched, the arrangement of the second display area DA2 may vary, and the boundary BD between the first display area DA1 and the second display area DA2 may vary.

Here, the first light sources LS1 disposed in the area corresponding to the second display area DA2 may be the first light sources LS1 disposed in the second display area DA2 in the third direction DR3. The second light sources LS2 disposed in the area corresponding to the second display area DA2 may be the second light sources LS2 disposed on one side and the other side of the second display area DA2 in the second direction DR2.

However, the embodiments of the present disclosure are not limited thereto, and the display area DA may be comprised of the second display area DA2 in which the share mode and the private mode may be variably switched in all areas.

Since the display apparatus 1 includes both the first display area DA1 and the second display area DA2, the driver and the front passenger may receive different images based on their viewing angles. Furthermore, since the second light source package 131 is disposed on the one side and the other side of the second light guide plate 132 in the second direction DR2, the second display area DA2 may vary in various ways, thereby improving user convenience. Furthermore, unnecessary manufacturing processes may be simplified, thereby reducing production energy.

Hereinafter, other embodiments of the present disclosure will be described. For contents that are substantially the same as those described with reference to FIGS. 1, 2, 3, 4, 5, 6, 7, and 8 among components included in other embodiments, the same reference numerals are given, and overlapping contents may be omitted or briefly described.

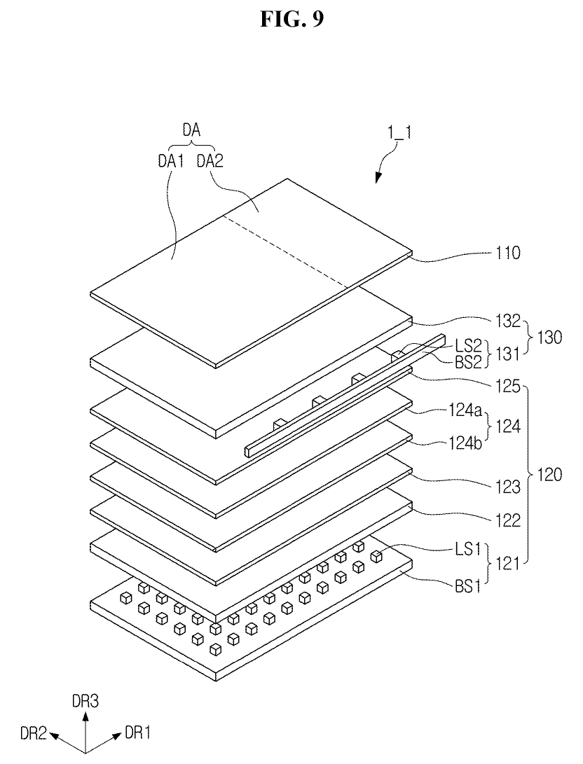

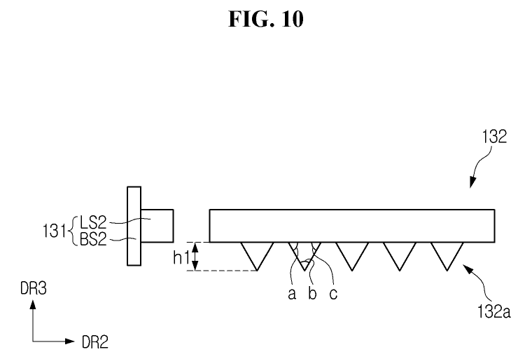

FIG. 9 is an exploded schematic perspective view of the display apparatus according to another embodiment of the present disclosure. FIG. 10 is a schematic view showing a second light guide plate and its peripheral cross-sectional structure according to another embodiment.

Referring to FIGS. 9 and 10, a display apparatus 1_1 according to the another embodiment of the present disclosure may include the second light guide plate 132 and the second light source package 131 disposed near the second light guide plate 132, but the second light source package 131 may be disposed on only one of one side and the other side of the second light guide plate 132 in the second direction DR2.

FIGS. 9 and 10 may show that the second light source package 131 is disposed only on one side of the second light guide plate 132 in the second direction DR2, but the embodiments of the present disclosure are not limited thereto. For example, the second light source package 131 may be disposed only on the other side of the second light guide plate 132, which is disposed on an opposite to the one side of the second light guide plate 132, in the second direction DR2.

In this case, the density per unit area of the light guide pattern 132a on the second light guide plate 132 may decrease as the light guide patterns 132a are adjacent to the second light source package 131 and increase as the light guide patterns 132a are farther away from the second light source package 131. The density per unit area of the light guide pattern 132a may increase from the other side to one side of the second light guide plate 132 in the second direction DR2.

As the density per unit area of the light guide pattern 132a increases as the light guide patterns 132a are farther away from the second light source package 131, the luminance uniformity based on the viewing angle of the display apparatus 1_1 may be improved.

Even in this case, since the second light sources LS2 of the second light source package 131 may each independently be driven, the sizes of the first display area DA1 and the second display area DA2 may vary, thereby providing the user with improved convenience.

In addition, since the second light source package 131 is disposed on only one of the one side and the other side of the second light guide plate 132 in the second direction DR2, the manufacturing process costs may be reduced, and the bezel of the display apparatus 1_1 may be reduced, thereby improving aesthetics.

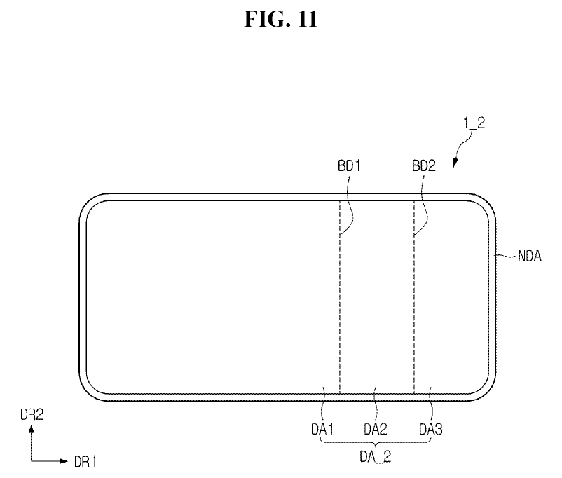

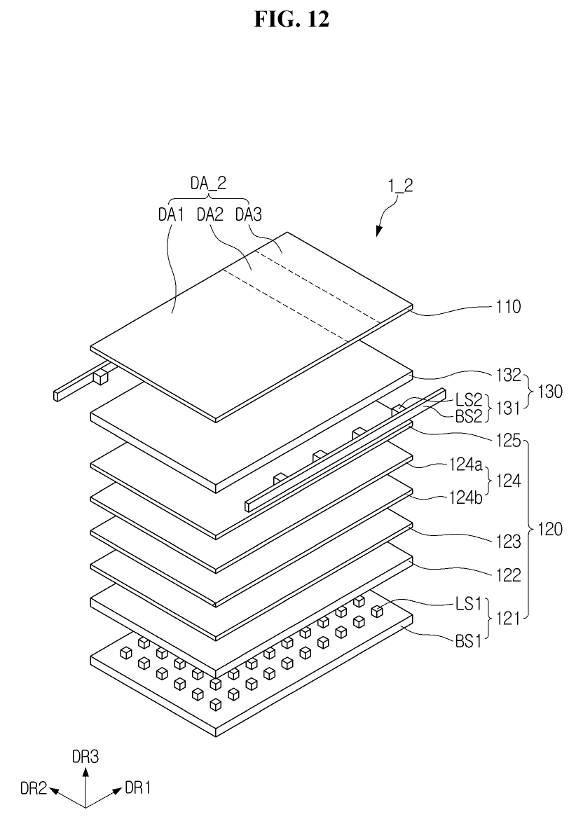

FIG. 11 is a schematic plan view of the display apparatus according to another embodiment. FIG. 12 is an exploded schematic perspective view of the display apparatus according to another embodiment.

Referring to FIGS. 11 and 12, a display apparatus 1_2 according to another embodiment may include a display area DA_2. The display area DA_2 may include a first display area DA1, a second display area DA2, and a third display area DA3. In addition, the display apparatus 1_2 according to another embodiment may include a first boundary BD1 disposed between the first display area DA1 and the second display area DA2 and a second boundary BD2 disposed between the second display area DA2 and the third display area DA3.

The first display area DA1, the second display area DA2, and the third display area DA3 may be sequentially disposed in the first direction DR1.

The first display area DA1 may operate in a first mode, and the second display area DA2 and the third display area DA3 may operate in the first mode and a second mode, respectively.

For example, the first mode may be a share mode, which does not limit a side viewing angle of the display apparatus 1_2. The second mode may be a private mode, which limits the side viewing angle of the display apparatus 1_2. In particular, the share mode may have a wide viewing angle, and the private mode may have a narrow viewing angle.

In particular, the first display area DA1 may maintain the share mode during the operation of the display apparatus 1_2. The second display area DA2 and the third display area DA3 may selectively operate in the share mode and the private mode during the operation of the display apparatus 1_2.

When each of the plurality of second light sources LS2 may be independently controlled and operated, the second display area DA2 and the third display area DA3 may each independently be variably switched from the share mode to the private mode or from the private mode to the share mode.

In addition, the sizes (or areas) of the first display area DA1, the second display area DA2, and the third display area DA3 may vary. In particular, when each of the plurality of second light sources LS2 may be each independently controlled and operated, the first boundary BD1 and the second boundary BD2 may move in the first direction DR1 by adjusting the number and arrangement of turned-on second light sources LS2.

When the first display area DA1 operates only in the share mode, the first light sources LS1 and the second light sources LS2 disposed in the area corresponding to the first display area DA1 may be maintained in the turned-on state.

When the second display area DA2 variably operates in the share mode and the private mode, the first light sources LS1 disposed in the area corresponding to the second display area DA2 may be maintained in a turned-on state. As the second light sources LS2 disposed in the area corresponding to the second display area DA2 are variably switched between the turned-on and turned-off states, the share mode and private mode of the second display area DA2 may be changed.

Based on the arrangement of the second light sources LS2 whose turn-on and turn-off states are variably switched, the arrangement of the second display area DA2 may vary, and the first boundary BD1 between the first display area DA1 and the second display area DA2 may vary.

When the third display area DA3 variably operates in the share mode and the private mode, the first light sources LS1 disposed in the area corresponding to the third display area DA3 may be maintained in a turned-on state. As the second light sources LS2 disposed in the area corresponding to the third display area DA3 are variably switched between the turned-on and turned-off states, the share mode and private mode of the third display area DA3 may be changed.

Based on the arrangement of the second light sources LS2 whose turn-on and turn-off states are variably switched, the arrangement of the third display area DA3 may vary, and the second boundary BD2 between the second display area DA2 and the third display area DA3 may vary.

Even in this case, since the second light sources LS2 of the second light source package 131 may each be independently driven, the sizes of the first display area DA1, the second display area DA2, and the third display area DA3 may vary, thereby providing the user with enhanced convenience.

In addition, since the display area in which the share mode and private mode may be variably switched is composed of the second display area DA2 and the third display area DA3, a screen display method of the display apparatus 1_2 may be more diverse, thereby providing the user with enhanced convenience of use of the display apparatus 1_2.

A display apparatus according to embodiments of the present disclosure may be described as follows.

According to the embodiments of the present disclosure, different images may be provided based on the viewing angle.

According to the embodiments of the present disclosure, the limited viewing angle area may be changed.

According to the embodiment of the present disclosure, the convenience of the user may be improved due to the change in the limited viewing angle area.

According to the embodiment of the present disclosure, the limited viewing angle area may be changed based on the user’s needs, thereby increasing the efficiency of the display apparatus and further simplifying the process. Accordingly, power consumption may be reduced, thereby reducing production energy.

According to embodiments of the present disclosure, there is provided a display apparatus including a plurality of first light sources, a diffusion sheet disposed on the first light sources, a prism sheet disposed on the diffusion sheet, a light control film disposed on the prism sheet, a light guide plate disposed on the light control film and having a long side extending in a first direction and a short side extending in a second direction intersecting the first direction, and a plurality of second light sources disposed to face the long side of the light guide plate, in which the plurality of second light sources are repeatedly disposed in the first direction and are each independently driven.

According to embodiments of the present disclosure, the display apparatus may further include a first display area operated in a share mode with a wide viewing angle, and a second display area in which the share mode with the wide viewing angle and a private mode with a narrow viewing angle is variably switched.

According to embodiments of the present disclosure, the first display area and the second display area may be disposed in the first direction.

According to embodiments of the present disclosure, when the second display area operates in a share mode, some of the plurality of second light sources corresponding to the second display area may be turned on, and when the second display area operates in a private mode, some of the plurality of second light sources corresponding to the second display area may be turned off.

According to embodiments of the present disclosure, when the first display area operates in a share mode, the remaining ones of the plurality of second light sources corresponding to the first display area may be turned on.

According to embodiments of the present disclosure, the light guide plate may

further include a plurality of light guide patterns disposed on a back surface opposite to the light control film, and a density per unit area of the plurality of light guide patterns may increase as the light guide patterns are farther away from the plurality of second light sources.

According to embodiments of the present disclosure, the plurality of second light sources may be disposed on both one side and the other side of the light guide plate in the second direction, and the density per unit area of the plurality of light guide patterns may increase from a long side of the light guide plate to a central portion of the light guide plate in the second direction.

According to embodiments of the present disclosure, the plurality of light guide patterns may have a pyramidal shape protruding toward the light control film, and slopes of the four side surfaces forming the pyramidal shape may all be the same. However, in another embodiment, slopes of the four side surfaces forming the pyramidal shape may be different.

According to embodiments of the present disclosure, the light control film may include a plurality of light-shielding patterns and patterned insulating films between the light-shielding patterns, and the plurality of light-shielding patterns may extend in the second direction and may be repeatedly disposed in the first direction.

According to embodiments of the present disclosure, the plurality of light-shielding patterns may have the same thickness in a thickness direction and may be repeatedly disposed at regular intervals in the first direction.

According to embodiments of the present disclosure, the prism sheet may include a first prism sheet and a second prism sheet that are sequentially stacked, and a prism pattern of the first prism sheet and a prism pattern of the second prism sheet may have axes that are orthogonal to each other.

According to embodiments of the present disclosure, the display apparatus may further include a display panel disposed on the light guide plate, in which the display panel may include a lower substrate, an upper substrate, and a liquid crystal layer between the lower substrate and the upper substrate.

According to embodiments of the present disclosure, the plurality of first light sources may be disposed below the diffusion sheet.

According to embodiments of the present disclosure, the plurality of second light sources may be disposed on only one of one side and the other side of the light guide plate in the second direction.

According to embodiments of the present disclosure, the light guide plate may further include a plurality of light guide patterns disposed on a back surface opposite to the light control film, and a density per unit area of the plurality of light guide patterns may increase as the light guide patterns are farther away from the plurality of second light sources.

According to embodiments of the present disclosure, there is provided a display apparatus including a first display area that operates in a share mode with a wide viewing angle, a second display area which is disposed at one side of the first display area in a first direction and in which the share mode with the wide viewing angle and a private mode with a narrow viewing angle are variably switched, a boundary between the first display area and the second display area, which extends in a second direction intersecting the first direction, a plurality of first light sources disposed across the first display area and the second display area, a light guide plate disposed on the first light sources, and a plurality of second light sources that are disposed to face a side surface of the light guide plate and are repeatedly disposed in the first direction, in which the boundary between the first display area and the second display area may move in the first direction according to turned-on and turned-off states of the plurality of second light sources.

According to embodiments of the present disclosure, when the second display area operates in a share mode, some of the plurality of second light sources corresponding to the second display area may be turned on, and when the second display area operates in a private mode, some of the plurality of second light sources corresponding to the second display area may be turned off.

According to embodiments of the present disclosure, when the first display area operates in a share mode, the remaining ones of the plurality of second light sources corresponding to the first display area may be turned on.

According to embodiments of the present disclosure, the light guide plate may further include a plurality of light guide patterns disposed on a back surface opposite to the plurality of first light sources, and a density per unit area of the plurality of light guide patterns may increase as the light guide patterns are farther away from the plurality of second light sources.

According to embodiments of the present disclosure, the plurality of second light sources may be disposed on both one side and the other side of the light guide plate in the second direction, and the density per unit area of the plurality of light guide patterns may increase from a side surface of the light guide plate toward a central portion of the light guide plate in the second direction.

Although certain embodiments and implementations have been described herein, other embodiments and modifications will be apparent from this description. Accordingly, the inventive concepts are not limited to such embodiments, but rather to the broader scope of the appended claims and various obvious modifications and equivalent arrangements as would be apparent to a person of ordinary skill in the art.

What is claimed is:

1. A display apparatus comprising:
a first light source package including a plurality of first light sources and a first substrate;
a diffusion sheet disposed on the first light source package;
a prism sheet disposed on the diffusion sheet;
a light control film disposed on the prism sheet;
a light guide plate disposed on the light control film and having a long side extending in a first direction and a short side extending in a second direction intersecting the first direction; and
a second light source package including a plurality of second light sources disposed to face the long side of the light guide plate and a second substrate,
wherein the plurality of second light sources are protruded from the second substrate in the second direction and repeatedly disposed in the first direction and are each independently driven.

2. The display apparatus of claim 1, further comprising:
a first display area configured to be operated in a share mode with a wide viewing angle; and
a second display area configured to be variably switched from the share mode with the wide viewing angle to a private mode with a narrow viewing angle.

3. The display apparatus of claim 2, wherein the first display area and the second display area are disposed in the first direction.

4. The display apparatus of claim 3, wherein, when the second display area operates in the share mode, some of the plurality of second light sources corresponding to the second display area are turned on, and
when the second display area operates in the private mode, some of the plurality of second light sources corresponding to the second display area are turned off.

5. The display apparatus of claim 2, wherein a boundary between the first display area and the second display area extends in the second direction, and
the boundary between the first display area and the second display area is variably changed in the first direction based on turn-on and turn-off of the plurality of second light sources.

6. The display apparatus of claim 1, wherein the light guide plate further includes a plurality of light guide patterns disposed on a bottom surface of the light guide plate, and
a density per unit area of the plurality of light guide patterns increases as the light guide patterns are farther away from the plurality of second light sources.

7. The display apparatus of claim 6, wherein the plurality of second light sources are disposed on both one side and the other side of the light guide plate in the second direction, and
a density per unit area of the plurality of light guide patterns increases from the long side of the light guide plate toward a central portion of the light guide plate in the second direction.

8. The display apparatus of claim 7, wherein each of the plurality of light guide patterns has a pyramidal shape protruding toward the light control film, and
slopes of the four side surfaces forming the pyramidal shape are all the same.

9. The display apparatus of claim 1, wherein the light control film includes a plurality of light-shielding patterns and patterned insulating films between the light-shielding patterns, and
the plurality of light-shielding patterns extend in the second direction and are repeatedly disposed in the first direction.

10. The display apparatus of claim 9, wherein the plurality of light-shielding patterns have a same thickness in a thickness direction and are repeatedly disposed at regular intervals in the first direction.

11. The display apparatus of claim 1, wherein the prism sheet includes a first prism sheet and a second prism sheet that are sequentially stacked in a thickness direction, and
a prism pattern of the first prism sheet and a prism pattern of the second prism sheet have axes that are orthogonal to each other.

12. The display apparatus of claim 1, further comprising a display panel disposed on the light guide plate,
wherein the display panel includes a lower substrate, an upper substrate, and a liquid crystal layer disposed between the lower substrate and the upper substrate.

13. The display apparatus of claim 1, wherein the plurality of first light sources are disposed below the diffusion sheet.

14. The display apparatus of claim 1, wherein the plurality of second light sources are disposed on either one side or the other side of the light guide plate in the second direction.

15. The display apparatus of claim 14, wherein the light guide plate further includes a plurality of light guide patterns disposed on a bottom surface of the light guide plate, and
a density per unit area of the plurality of light guide patterns increases as the light guide patterns are farther away from the plurality of second light sources.

16. A display apparatus comprising:
a first display area that operates in a share mode with a wide viewing angle;
a second display area which is disposed at one side of the first display area in a first direction and in which the share mode with the wide viewing angle and a private mode with a narrow viewing angle are variably switched;
a boundary disposed between the first display area and the second display area, which extends in a second direction intersecting the first direction;
a plurality of first light sources disposed across the first display area and the second display area;
a light guide plate disposed on the first light sources; and
a plurality of second light sources that are disposed to face a side surface of the light guide plate and are repeatedly disposed in the first direction,
wherein the boundary disposed between the first display area and the second display area changeably moves in the first direction based on turned-on and turned-off states of the plurality of second light sources.

17. The display apparatus of claim 16, wherein, when the second display area operates in the share mode, some of the plurality of second light sources corresponding to the second display area are turned on, and
when the second display area operates in the private mode, some of the plurality of second light sources corresponding to the second display area are turned off.

18. The display apparatus of claim 17, wherein, when the first display area operates in the share mode, a remaining ones of the plurality of second light sources corresponding to the first display area are turned on.

19. The display apparatus of claim 16, wherein the light guide plate further includes a plurality of light guide patterns disposed on a bottom surface of the light guide plate, and
a density per unit area of the plurality of light guide patterns increases as the light guide patterns are farther away from the plurality of second light sources.

20. The display apparatus of claim 19, wherein the plurality of second light sources are disposed on both one side and the other side of the light guide plate in the second direction, and
a density per unit area of the plurality of light guide patterns increases from the side surface of the light guide plate toward a central portion of the light guide plate in the second direction.
